(19) United States
(12) Patent Application Publication
(10) Pub. No.: US 2006/0279206 A1
(43) Pub. Date: Dec. 14, 2006

(54) ORGANIC EL ELEMENT, ORGANIC EL DISPLAY USING SAME AND MANUFACTURING METHOD FOR ORGANIC EL ELEMENT

(75) Inventors: Shimoji NORIYUKI, Ukyo-ku, Kyoto (JP); Moriwake MASATO, Ukyo-ku, Kyoto (JP); Takaaki FUCHIKAMI, Ukyo-ku, Kyoto (JP); Hiroki KATO, Ukyo-ku, Kyoto (JP)

Correspondence Address: ROHM CO., LTD.;C/O KEATING & BENNETT, LLP, 8180 GREENSBORO DRIVE, SUITE 850, MCLEAN, VA, 22102, US

(73) Assignee: ROHM CO., LTD., Ukyo-ku (JP)

(21) Appl. No.: 11/423,372

(22) Filed: Jun. 9, 2006

(30) Foreign Application Priority Data
Jun. 9, 2005 (JP) 2005-169213

(51) Int. Cl. H01L 51/50; H01L 51/56; H05B 33/12

(52) U.S. Cl. 313/506; 313/504; 428/690; 428/917; 427/66; 438/22; 438/34; 257/88

(57) ABSTRACT

An organic EL element includes an anode and a cathode which are arranged so as to face each other and an organic layer which is disposed between the anode and cathode and includes a light emitting layer. The organic layer may also include a hole transport layer that includes a base material and an Mo oxide. Alternatively, an Mo oxide layer is disposed between the anode and the organic layer.

### BACKGROUND OF THE INVENTION

1. Field of the Invention

The present invention relates to an organic EL element in which an organic layer is interposed between a pair of electrodes and an electrical field is applied to this organic layer, and thereby, light is emitted. The present invention also relates to an organic EL display including such an organic EL element and a manufacturing method for an organic EL element.

2. Description of the Related Art

FIG. 14 shows a conventional organic EL element (see for example JP H2004-247106). Organic EL element X shown in this figure is provided with a metal reflective film 92 and a multilayered transparent electrode 93, which is an anode, on a transparent substrate 91. An organic layer 94 is disposed between multilayer transparent electrode 93 and a transparent electrode 95 which is a cathode. Organic layer 94 is made of a hole injection layer 94a, a hole transport layer 94b, a light emitting layer 94c, an electron transport layer 94d, and an electron injection layer 94e. When an electrical field is applied between multilayered transparent electrode 93 and transparent electrode 95, light emitting layer 94c emits light. Some of the light is directed upward in the figure, and this light transmits through transparent electrode 95 and is emitted upward in the figure from organic EL element X. Meanwhile, light which is directed downward in the figure transmits through multilayered transparent electrode 93 and is reflected from reflective metal film 92. The reflected light transmits through multilayered transparent electrode 93, organic layer 94, and transparent electrode 95, and is emitted upward in the figure from organic EL element X. In this manner, organic EL element X is formed as a so-called top emission type organic EL element which emits light from the side opposite to transparent substrate 91.

However, the demand for an increase in the brightness and reduction in the power consumption of organic EL element X has been rising year by year.

First, concerning the increase in the brightness, light which is directed downward in the figure from light emitting layer 94c transmits through multilayered transparent electrode 93 twice in organic EL element X. Although multilayered transparent electrode 93 is formed of a material having relatively high light transmittance, such as, for example, ITO (Indium Tin Oxide), attenuation of light which transmits through multilayered transparent electrode 93 as described above cannot be avoided. Therefore, the amount of light that is emitted from organic EL element X is reduced by the amount of attenuation in multilayered transparent electrode 93.

In addition, concerning the reduction in power consumption, it is effective to provide a configuration having higher current density when the same voltage is applied, in order for organic EL element X to be driven efficiently for better light emission. In order to increase this current density, it is necessary to improve the efficiency of hole injection from multilayered transparent electrode 93, which is an anode, to organic layer 94. This efficiency of hole injection is determined by the difference in the work function between multilayered transparent electrode 93 and hole injection layer 94a. It is preferable to increase the work function of multilayered transparent electrode 93 and thus reduce the difference in the above-described work function. In the case of multilayered transparent electrode 93 made of ITO, the work function is approximately 4.8 eV, which in some cases is insufficient for increasing the current density as described above.

### SUMMARY OF THE INVENTION

In order to overcome the problems described above, preferred embodiments of the present invention provide an organic EL element which makes it possible to achieve increases in the brightness and reductions in the power consumption, an organic EL display including an organic EL element, and a manufacturing method for an organic EL element.

An organic EL element according to a preferred embodiment of the present invention includes an anode and a cathode arranged so as to face each other, an organic layer which is disposed between the anode and cathode and includes a light emitting layer, and an Mo oxide layer is disposed between the anode and the organic layer.

In this unique configuration, it is possible to minimize the difference in the work function between the Mo oxide layer and the organic layer, so that the efficiency of hole injection into the organic layer is improved. As a result, the current density when a constant voltage is applied to the organic EL element can be increased. Accordingly, it is possible for the organic EL element to be driven for efficient light emission, and reduction in the power consumption of the organic EL element can be achieved.

In a preferred embodiment of the present invention, the Mo oxide layer is preferably made of MoO₃. This configuration is appropriate for improving the efficiency of hole injection from the Mo oxide layer to the organic layer.

In another preferred embodiment of the present invention, the Mo oxide layer preferably has a thickness of about 3.5 Å to about 1,000 Å. In this configuration, it is possible to improve the efficiency of hole injection while improving the light transmittance of the Mo oxide layer, which is advantageous for increasing the brightness of the organic EL element. In addition, the present inventors discovered through experiment that a current density of no less than about 10 mA/cm² can be gained when a voltage of approximately 5 V, for example, is applied. This is appropriate for making it possible for the organic EL light emitting element to be driven for efficient light emission.

In a preferred embodiment of the present invention, the Mo oxide layer preferably has a thickness of about 10 Å to about 100 Å. The inventors discovered through experiment that in this configuration, a current density of no less than about 80 mA/cm² can be gained when a voltage of, for example, approximately 5 V is applied. This is appropriate for making it possible for the organic El element to be driven for efficient light emission.

In a preferred embodiment of the present invention, the anode is preferably made of Al. In this configuration, the light reflectance of the anode can be relatively high. As a result, it is possible to make more of the light that is emitted from the light emitting layer in the organic layer reflect from the anode. Accordingly, this is appropriate for achieving an increase in the brightness in the organic EL element having a so-called top emission type configuration.

An organic EL display provided according to another preferred embodiment of the present invention includes a substrate, a plurality of organic EL elements according to the above-described preferred embodiment of the present invention, and an active matrix circuit for driving the plurality of organic EL elements for light emission. In this configuration, an increase in the brightness and a reduction in the power consumption of the organic EL display can be achieved.

In another preferred embodiment of the present invention, the Mo oxide layers of adjacent organic EL elements of the plurality of organic EL elements are connected to each other. In this configuration, it is possible to integrally form the Mo oxide layers such that the Mo oxide layers cover the substrate, which is advantageous. In this configuration, there is no inappropriate conduction between anodes of adjacent organic EL elements as those described above when the Mo oxide layer is formed as a sufficiently thin layer.

In a preferred embodiment of the present invention, the substrate is preferably a silicon substrate and the active matrix circuit is formed so as to have a plurality of transistors on the substrate. In this configuration, it is possible to easily carry out microscopic processing for the formation of the transistors. Accordingly, it is possible to increase the density of the plurality of organic EL elements, and thus, an increase in the precision of the EL display can be achieved.

A manufacturing method for an organic EL element according to a further preferred embodiment of the present invention includes the steps of forming an anode, forming an organic layer that includes a light emitting layer, forming a cathode, and forming an Mo oxide layer after the step of forming an anode and before the step of forming an organic layer. In this configuration, an appropriate organic EL element according to the above-described preferred embodiment of the present invention can be manufactured.

In a preferred embodiment of the present invention, the Mo oxide layer is preferably formed from MoO₃ in the step of forming an Mo oxide layer. This configuration is appropriate for increasing the effects of reduction in the power consumption of the organic EL element.

In a preferred embodiment of the present invention, in the step of forming an Mo oxide layer, a vapor deposition method is used. In this configuration, it is possible to form an Mo oxide layer relatively uniformly, which is advantageous for achieving reduction in the power consumption of the organic EL element. In addition, the inventors discovered through experiment that Mo oxide layers formed using a vapor deposition method allow a significantly higher current density to be gained from the same voltage than Mo oxide layers formed using a sputtering method. This is advantageous for making it possible for the organic EL light emitting element to be driven for efficient light emission.

In a preferred embodiment of the present invention, the rate of vapor deposition is preferably about 0.1 Å/sec to about 1.0 Å/sec in the vapor deposition method. This configuration is appropriate for achieving reduction in the power consumption of the organic EL element.

An organic EL element according to another preferred embodiment of the present invention includes an anode and a cathode arranged so as to face each other, and an organic layer disposed between the anode and cathode and includes a light emitting layer and a hole transport layer, wherein the hole transport layer includes a base material and an Mo oxide. In this configuration, reduction in the power consumption of the organic EL element can be achieved.

In a preferred embodiment of the present invention, the Mo oxide is preferably MoO₃. This configuration is appropriate for reducing the power consumption of the organic EL element.

In a preferred embodiment of the present invention, the base material is preferably made of α-NPD, TPD or TPTE.

In a preferred embodiment of the present invention, the anode is made of Al. In this configuration, an increase in the brightness of the organic EL element can be achieved.

An organic EL display provided according to yet another preferred embodiment of the present invention includes a substrate, a plurality of organic EL elements which are supported by the substrate and have the structure according to the above-described preferred embodiment of the present invention, and an active matrix circuit for driving the plurality of organic EL elements for light emission. In this configuration, an increase in the brightness and a reduction in the power consumption of the organic EL display can be achieved.

In a preferred embodiment of the present invention, the substrate is preferably a silicon substrate, and the active matrix circuit includes a plurality of transistors on the substrate. In this configuration, an increase in the precision of the described organic EL display can be achieved.

A manufacturing method for an organic EL element according to another preferred embodiment of the present invention includes the steps of forming an anode, forming an organic layer which includes a light emitting layer and a hole transport layer, and forming a cathode, wherein the step of forming an organic layer includes the step of forming a hole transport layer by vapor depositing a base material and an Mo oxide together. In this configuration, an appropriate organic EL element according to the above-described preferred embodiment of the present invention can be manufactured.

In a preferred embodiment of the present invention, MoO₃ is preferably used as the Mo oxide in the step of forming a hole transport layer. This configuration is appropriate for improving the effects of reducing the power consumption of the organic EL element, due to the Mo oxide layer.

Other features, elements, steps, characteristics and advantages of the present invention will become more apparent from the following detailed description of preferred embodiments of the present invention with reference to the attached drawings.

### BRIEF DESCRIPTION OF THE DRAWINGS

FIG. 1 is a cross sectional diagram showing the main portion of an organic EL element according to a first preferred embodiment of the present invention.

FIG. 2 is a cross sectional diagram showing the main portion of an example of an organic EL display including the organic EL elements shown in FIG. 1.

FIG. 3 is a cross sectional diagram showing the main portion of the organic EL display shown in FIG. 2 and illustrating a step for forming an active matrix circuit in an example of a manufacturing method for an organic EL display.

FIG. 4 is a cross sectional diagram showing the main portion of the organic EL display shown in FIG. 2 and illustrating a step for forming a conductive thin film in an example of a manufacturing method for an organic EL display.

FIG. 5 is a cross sectional diagram showing the main portion of the organic EL display shown in FIG. 2 and illustrating a step for forming an anode in an example of a manufacturing method for an organic EL display.

FIG. 6 is a cross sectional diagram showing the main portion of the organic EL display shown in FIG. 2 and illustrating a step for forming an Mo oxide layer in an example of a manufacturing method for an organic EL display.

FIG. 7 is a cross sectional diagram showing the main portion of the organic EL display shown in FIG. 2 and illustrating a step for forming an organic layer in an example of a manufacturing method for an organic EL display.

FIG. 8 is a cross sectional diagram showing the main portion of the organic EL display shown in FIG. 2 and illustrating a step for forming a cathode in an example of a manufacturing method for an organic EL display.

FIG. 9 is a graph showing the correlation between the method for forming an Mo oxide and the voltage-current characteristics.

FIG. 10 is a graph showing the correlation between the film thickness of the Mo oxide and the current density.

FIG. 11 is a graph showing the voltage-current characteristics of the organic EL element shown in FIG. 1.

FIG. 12 is a cross sectional diagram showing the main portion of an organic EL element according to a second preferred embodiment of the present invention.

FIG. 13 is a cross sectional diagram showing the main portion of an example of an organic EL display including organic EL elements shown in FIG. 12.

FIG. 14 is a cross sectional diagram showing the main portion of an example of an organic EL element according to the prior art.

### DETAILED DESCRIPTION OF PREFERRED EMBODIMENTS

In the following, the preferred embodiments of the present invention are specifically described in reference to the drawings.

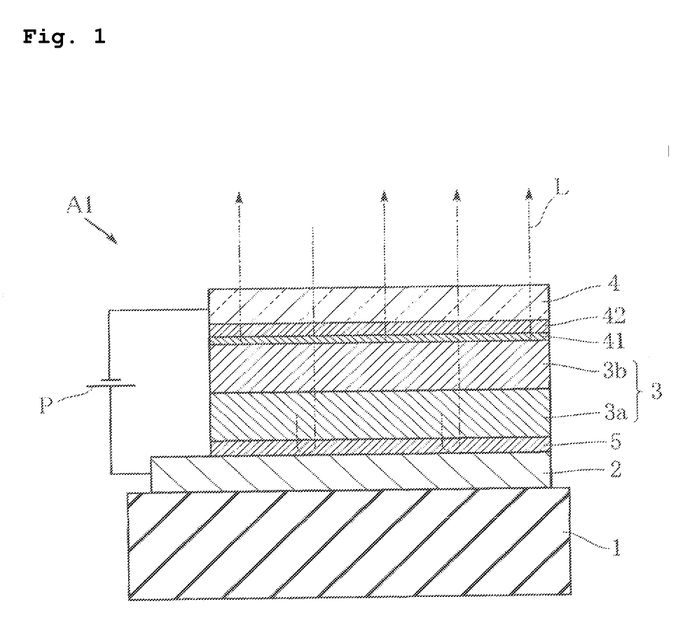

FIG. 1 shows an organic EL element according to a first preferred embodiment of the present invention. This organic EL element A1 preferably includes an anode 2, an Mo oxide layer 5, an organic layer 3, and a cathode 4, and is disposed on a substrate 1. As described below, organic EL element A1 is preferably a so-called top emission type organic EL element that emits light L in the upward direction in the figure.

Substrate 1 is an insulating substrate for supporting organic EL element A1.

Anode 2 is for applying an electrical field to organic layer 3 and injecting holes, and is electrically connected to the + electrode of power supply P. In the present preferred embodiment, anode 2 is made of Al and is a layer having relatively high reflectance.

Mo oxide layer 5 is formed on anode 2 so as to improve the efficiency of hole injection into organic layer 3, and in some cases, is referred to as a buffer layer. Mo oxide layer 5 is preferably formed of MoO₃ using, for example, a vapor deposition method or other suitable method. In the present preferred embodiment, Mo oxide layer 5 has a thickness of approximately 50 Å, for example. It is appropriate for Mo oxide layer 5 to have a thickness of approximately 3.5 Å to 1,000 Å, for example, in order to gain sufficient effects as those described below, as intended by the present invention, and it is preferable for it to have a thickness of approximately 10 Å to 100 Å.

Organic Layer 3, in which a hole transport layer 3a and a light emitting layer 3b are layered, is sandwiched between anode 2 and cathode 4.

Hole transport layer 3a is a layer for transporting holes which have been injected from anode 2 via Mo oxide layer 5 to light emitting layer 3b. In the present preferred embodiment, hole transport layer 3a is preferably formed of N, N′-bis(1-naphthyl)-N,N′-diphenyl-1,1′-biphenyl-4,4′-diamine (α-NPD) and has a thickness of approximately 500 Å. Triphenylamine derivatives (TPD) or the tetramer of phenyl amine (TPTE) may be used instead of α-NPD as the material for hole transport layer 3a.

Light emitting layer 3b is formed on hole transport layer 3a, and is a portion in which holes that have been injected from anode 2 and electrons that have been injected from cathode 4 recombine, and thereby, light is emitted. Light emitting layer 3b is made of, for example, an aluminum complex to which three oxines coordinate (hereinafter referred to as Alq₃), and has a thickness of approximately 500 Å.

Although in organic layer 3, Alq₃, which has relatively high electron transport performance, is preferably used as the material for light emitting layer 3b, and a two-layer structure of hole transport layer 3a and light emitting layer 3b is selected, in order to improve the balance between injection of holes and injection of electrons, this is only one example of a configuration for an organic layer according to the present invention. In the configuration, a hole injection layer, an electron transport layer, an electron injection layer and the like may be provided, unlike in the present preferred embodiment.

Cathode 4 is for applying an electrical field to organic layer 3 and injecting electrons, and is electrically connected to the − electrode of power supply P. Cathode 4 is formed on light emitting layer 3b preferably of organic layer 3 via an LiF layer 41 and an MgAg layer 42, and is a transparent electrode made of, for example, ITO. LiF layer 41, MgAg layer 42 and cathode 4 preferably have a thickness of, for example, approximately 5 Å, 50 Å and 1,000 Å, respectively. As for the material for cathode 4, IZO (Indium Zinc Oxide) may be used instead of ITO.

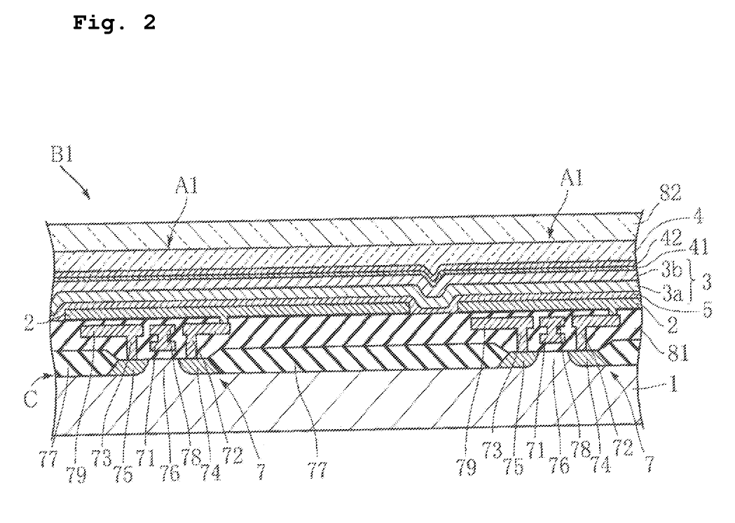

FIG. 2 shows an example of an organic EL display including a plurality of organic EL elements A1. Organic EL display B1 shown in this figure is provided with a substrate 1, an active matrix circuit C, and a plurality of organic EL elements A1. In organic EL display B1, a plurality of organic EL elements A1 are arranged in a matrix form and its configuration allows an image, or the like, facing upward in the figure to be displayed.

Substrate 1 is preferably, for example, a single crystal silicon substrate. Active matrix circuit C is formed on top of substrate 1.

Active matrix circuit C functions to drive the plurality of organic EL elements A1 for light emission and is provided with a plurality of transistors 7, gate wires 78, data wires 79, and other wires (not shown).

A plurality of transistors 7 function to switch the plurality of organic EL elements A1 and are formed as a so-called MOS (Metal Oxide Semiconductor) type transistor having a gate electrode 71, a source electrode 72, a drain electrode 73, an N source region 74, an N⁺ drain region 75, and a channel region 76.

N⁺ source region 74, N drain region 75, and channel region 76 are portions for implementing the switching function of a transistor 7. Gate electrode 71 is electrically connected to a gate wire 78 in order to generate an electrical field which works on channel region 76 and is provided above channel region 76 in the figure via an insulating layer 81. Gate electrode 71 is converted to a state of a high or low potential, and thereby, transistor 7 is converted to an ON or OFF state so that organic EL element A1 is switched. Source electrode 72 is electrically connected to an anode 2 of organic EL element A1. Drain electrode 73 is electrically connected to a data wire 79. When transistor 7 is converted to the ON state, a current flows between source electrode 72 and drain electrode 73. As a result, an electrical field is applied to organic EL element A1 so that organic EL element A1 emits light. The plurality of transistors 7 are covered with insulating layer 81. Adjacent transistors 7 are isolated by a field oxide film 77.

A plurality of organic EL elements A1 are formed in a matrix form on top of insulating layer 81. Although these organic EL elements A1 have the configuration that is described in reference to FIG. 1, Mo oxide layers 5, organic layers 3 and cathodes 4 of adjacent organic EL elements A1 are connected to each other in organic EL display B1. Mo oxide layer 5 has a high electric conductivity but a thickness as small as, for example, approximately 50 Å, and therefore, the electric resistance of substrate 1 in the plane is relatively high. As a result, an inappropriate current does not flow between adjacent organic EL elements. Cathode 4 is a common electrode in organic EL display B1.

Protective layer 82 is arranged so as to cover the plurality of organic EL elements A1. In protective layer 82, glass, into which a drying agent has been mixed, and an ultra violet ray curing resin, which seals the glass, are layered, and the resulting light transmittance is relatively high.

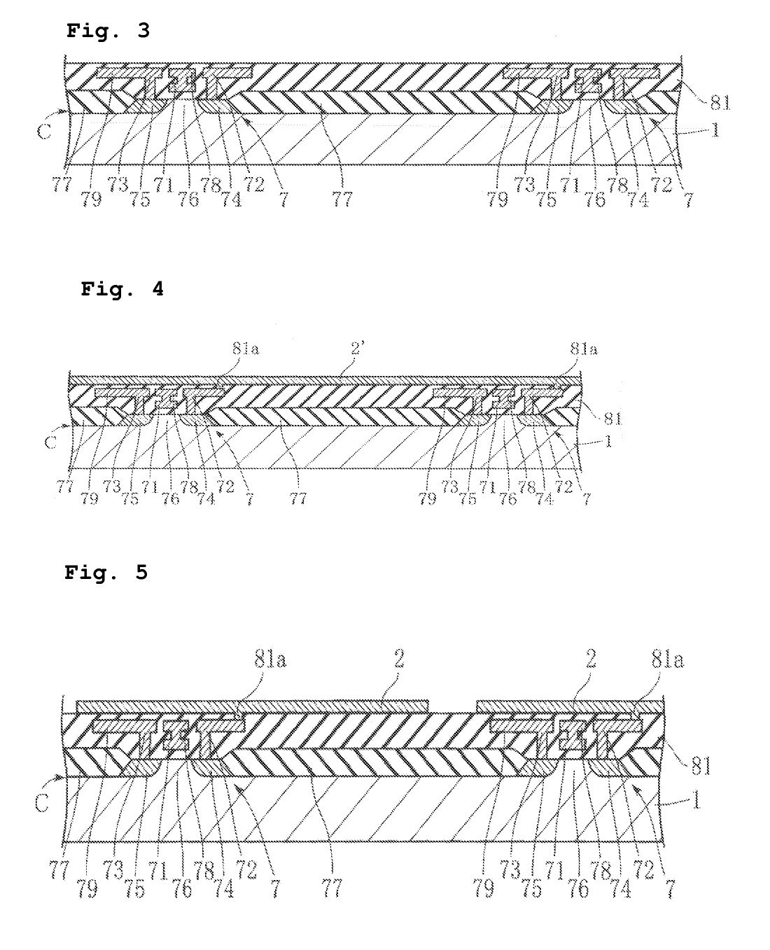

Next, an example of a manufacturing method for an organic EL display B1 is described below in reference to FIGS. 3 to 8. This manufacturing method includes an example of a manufacturing method for an organic EL element A1.

First, as shown in FIG. 3, a substrate 1 made of single crystal silicon is prepared, and an active matrix circuit C having a plurality of transistors 7 is formed on top of this substrate 1.

Next, as shown in FIG. 4, a conductive thin film 2′ is formed on top of insulating layer 81. Prior to the formation of conductive thin film 2′, a plurality of conduct holes 81a are created in insulating layer 81 via etching or other suitable process. Each conduct hole 81a reaches source electrode 72 of a transistor 7. After the formation of a plurality of conduct holes 81a, a sputtering process using, for example, Al is carried out on top of insulating layer 81. This sputtering process is carried out by making Ar plasma collide with an Al target within a vacuum chamber of which the degree of vacuum is approximately 1.0×10⁻⁶ Pa. As a result of this sputtering process, a conductive thin film 2′ made of Al having a thickness of approximately 1,000 Å is formed.

After the formation of conductive thin film 2′, as shown in FIG. 5, a plurality of anodes 2 are formed. Conductive thin film 2′ is patterned using a photolithographic technique, and after that, the resist used for this patterning is removed and this substrate is washed, and thereby, anodes 2 are formed. This patterning is carried out in such a manner that each electrode 2 has a portion which enters into a conduct hole 81a. As a result, each electrode 2 can be electrically connected to each source electrode 72.

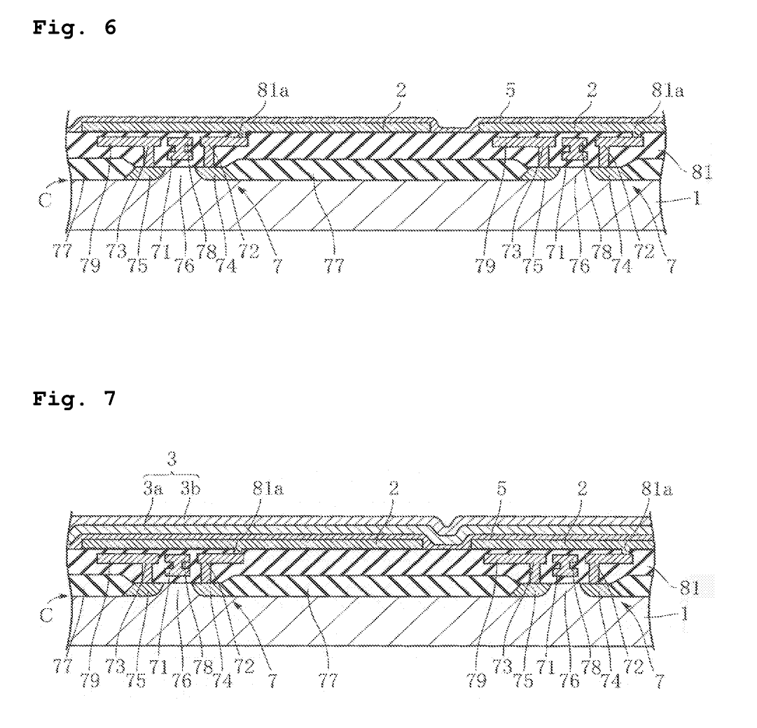

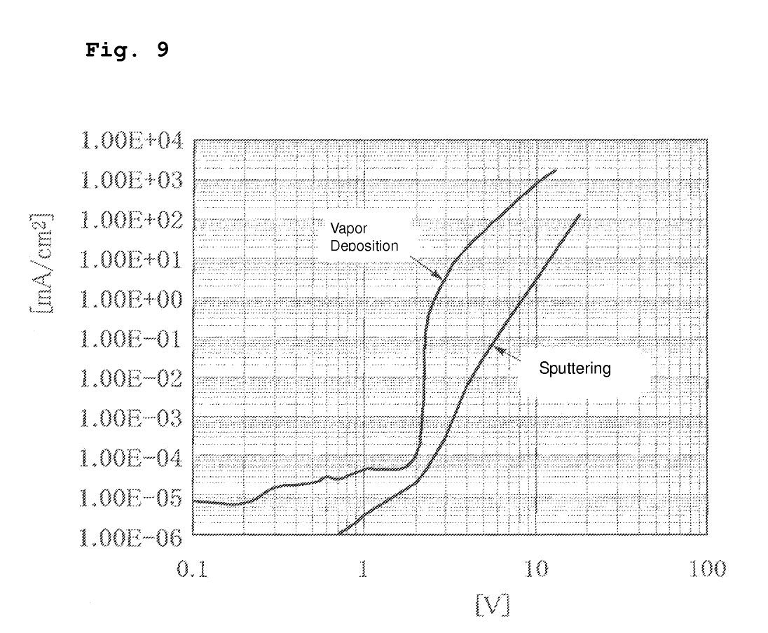

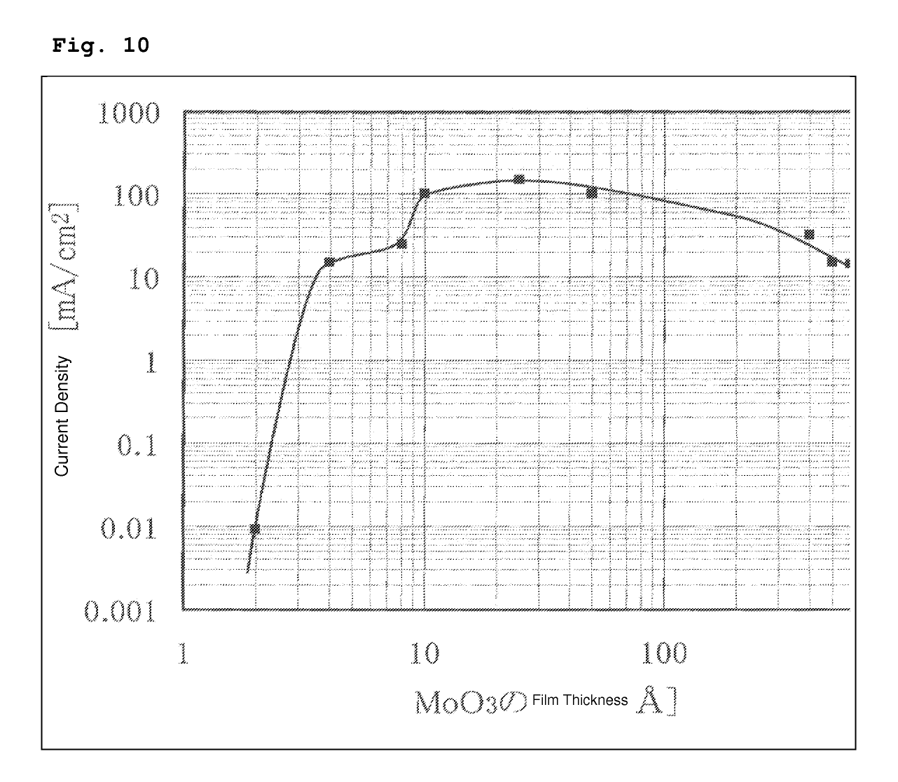

Next, as shown in FIG. 6, Mo oxide layer 5 is formed so as to cover the plurality of anodes 2 and insulating layer 81. Mo oxide layer 5 is formed in accordance with a vapor deposition method using Mo in an oxidizing atmosphere. As a result, Mo oxide layer 5 made of MoO₃ can be formed so as to have a thickness of approximately 50 Å. It is possible to finish Mo oxide layer 5 as a relatively uniform layer in accordance with a vapor deposition method. In particular, it is preferable to adjust the rate of vapor deposition to approximately 0.1 Å/sec to 1.0 Å/sec in the vapor deposition method in order to make Mo oxide layer 5 uniform. In addition, it was discovered by the inventors through experiment that in the case where Mo oxide layer 5 is formed in accordance with a vapor deposition method, as shown in FIG. 9, the current density that is gained by the same voltage becomes much higher than that in an Mo oxide layer formed in accordance with a sputtering method. This is appropriate for driving organic EL elements A1 for efficient light emission. Meanwhile, Mo oxide layer 5 with an extremely small thickness of approximately 50 Å makes contact with each of a plurality of anodes 2, and therefore, the electric resistance in the portions for connecting adjacent anodes 2 is extremely high. As a result, it is possible to make adjacent anodes 2 be in a substantially isolated state without carrying out patterning, or the like, on Mo oxide layer 5, and thus, the manufacturing process can be simplified.

After the formation of Mo oxide layer 5, as shown in FIG. 7, an organic layer 3 is formed. First, a hole transport layer 3a is formed on Mo oxide layer 5 in accordance with a vacuum vapor deposition method using α-NPD. The thickness of hole transport layer 3a is approximately 500 Å. TPD or TPTE may be used instead of α-NPD as the material for hole transport layer 3a. Next, a light emitting layer 3b is formed on top of hole transport layer 3a in accordance with a vacuum vapor deposition method using Alq₃. The thickness of light emitting layer 3b is approximately 500 Å.

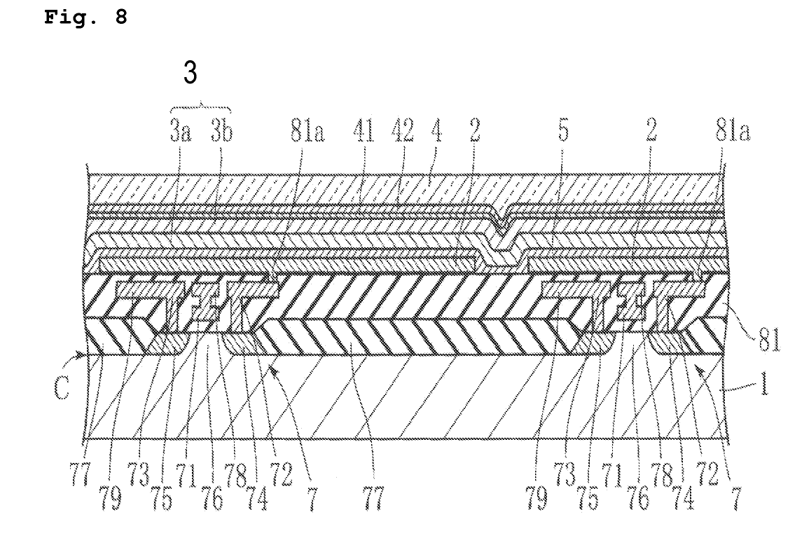

After the formation of organic layer 3, as shown in FIG. 8, an LiF layer 41 and an MgAg layer 42 are layered so as to cover organic layer 3. LiF layer 41 and MgAg layer 42 are formed in accordance with, for example, a vacuum vapor deposition method so as to have a thickness of about 5 Å and about 50 Å, respectively. Then, a cathode 4 is formed in accordance with a sputtering method using ITO, a molecular beam epitaxy method (MBE method), an ion plating method, or other suitable process. The thickness of cathode 4 is approximately 1,000 Å.

After the formation of cathode 4, cathode 4 is coated with glass into which a drying agent has been mixed, and this glass is sealed with an ultraviolet ray curing resin. As a result, protective layer 82 shown in FIG. 2 is formed and organic EL display B1 having a plurality of organic EL elements A1 is provided.

Next, the working effects of organic EL element A1 and organic EL display B1 including the same are described. According to the present preferred embodiment, as shown in FIG. 1, it is possible for light L to be emitted from light emitting layer 3b, and for some of this light to be directed upward in the figure to transmit through cathode 4 which is formed as a so-called transparent electrode so as to be emitted upward in the figure. LiF layer 41 and AgMg layer 42 have a thickness of approximately 5 Å and 50 Å, respectively, and therefore, the light transmittance is relatively high and prevents light L from light emitting layer 3b from attenuating, which would be inappropriate. Meanwhile, some of light L is directed downward in the figure, and first transmits through hole transport layer 3a. Next, Mo oxide layer 5 is a thin layer of approximately 50 Å having relatively high light transmittance, and therefore, allows light L to transmit. Light L that has transmitted through Mo oxide layer 5 is directed toward anode 2. Anode 2 is preferably made of Al, and therefore, has relatively high reflectance. As a result, light L that is directed downward in the figure is reflected from anode 2, and after that transmits through Mo oxide layer 5, organic layer 3, LiF layer 41, AgMg layer 42 and cathode 4 so as to be emitted upward in the figure. Accordingly, it is possible to increase the amount of light that is emitted upward in the figure from organic EL element A1 in comparison with the configuration having an anode made of ITO, as shown in, for example, FIG. 14, and thus, an increase in the brightness of organic EL element A1, which is of a so-called top emission type, can be achieved. As a result of this, the image quality of organic display B1 shown in FIG. 2 can be improved.

In addition, it is possible to achieve reduction in the power consumption of organic EL element A1 by providing Mo oxide layer 5. FIG. 10 shows the relationship between the film thickness of MO oxide layer 5 and the current density that is gained when a voltage of 5 V is applied, as discovered by the present inventors through experiment. The thickness of Mo oxide layer 5 is about 50 Å, and therefore, a current density which exceeds about 100 mA/cm² is produced. As a result, it is possible to improve the voltage-current characteristics of organic EL light emitting element A1 as a whole, as described below, and thus, organic EL light emitting element A1 is appropriately driven for efficient light emission. Here, when the thickness of Mo oxide layer 5 is approximately 10 Å to 100 Å, a current density of no less than approximately 80 mA/cm² is produced, which is preferable for efficient drive for light emission. In addition, when the thickness of Mo oxide layer 5 is approximately 3.5 Å to 1000 Å, a current density of no less than approximately 10 mA/cm² is produced, and any value within this range can achieve reduction in the power consumption.

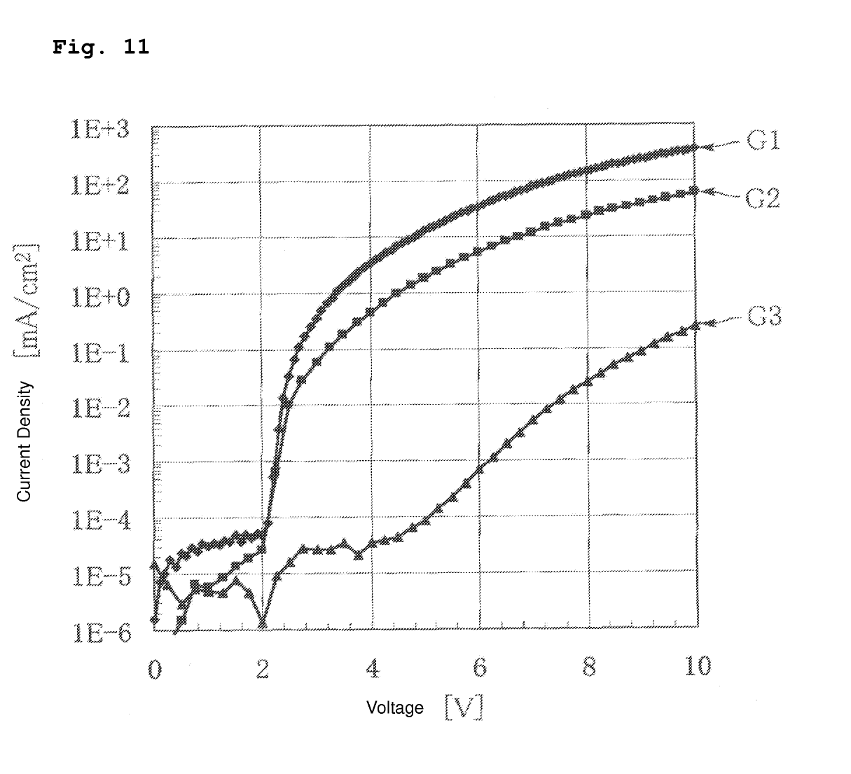

FIG. 11 shows the voltage-current characteristics in organic EL element A1. The lateral axis indicates the voltage that is applied to organic EL element A1. The vertical axis indicates the current density induced by the voltage, and is an axis showing a logarithmic scale. It is shown that the greater the current density is for a constant voltage, the more efficiently light can be emitted. In the graph shown in this figure, curve G1 plots the results of measurement of the voltage-current characteristics of organic EL element A1 according to the present preferred embodiment. As a comparative example, curve G2 plots the results of measurement for the configuration where a transparent electrode such as ITO is used as an anode in the same manner as in the prior art shown in FIG. 14. As another comparative example, curve G3 plots the results of measurement for the configuration where an anode made of Al and a pole transport layer made of α-NPD make direct contact.

First, it can be seen from comparison between curve G2 and curve G3 that the current density lowers from about 1/100 to approximately 1/1000 when the material of the anode is changed from ITO to Al. That is to say, the anode is changed to one made of Al in order to improve the efficiency of reflection from the anode without affecting other areas, the power consumption increases significantly from the prior art, which is adverse to the goal of reducing power consumption.

Next, it is evident from comparison between curve G1, curve G2 and curve G3 that the current density of organic EL element A1 is significantly higher than in the comparative example where an anode made of Al is provided, as indicated by curve G3. In addition, the current density of organic EL element A1 is approximately ten times higher than in the configuration indicated by curve G2 in the voltage range shown in the figure. This is because the work function of ITO is approximately 4.8 eV, while the work function of Mo oxide layer 5 made of MoO₃ has a value which is close to the work function of hole transport layer 3a made of α-NPD (approximately 5.42 eV). That is to say, it is considered that Mo oxide layer 5 functions to increase the efficiency of hole injection, that is, as a so-called buffer layer, in organic EL element A1 according to the present preferred embodiment. In this manner, it is possible to increase the current density by increasing the efficiency of hole injection of organic EL element A1 according to the present preferred embodiment. Accordingly, it is possible to drive organic EL element A1 for efficient light emission, and reduction in the power consumption of organic EL element A1 can be achieved. In addition, reduction in the power consumption can, of course, be achieved in organic EL display B1. Here, it was discovered by the inventors through experiment that the efficiency of hole injection can be increased to an appropriate level when the thickness of Mo oxide layer 5 is approximately 10 Å to 100 Å.

It is possible in organic EL display B1 to place a plurality of transistors 7 with high density on substrate 1 made of single crystal silicon, and thus, active matrix circuit C can be formed as a so-called integrated circuit. Accordingly, this is appropriate for increasing the density of the plurality of organic EL elements A1 and increase in the precision of organic EL display B1 can be achieved. Here, active matrix circuit C may be provided with a plurality of thin film transistor (TFT) elements.

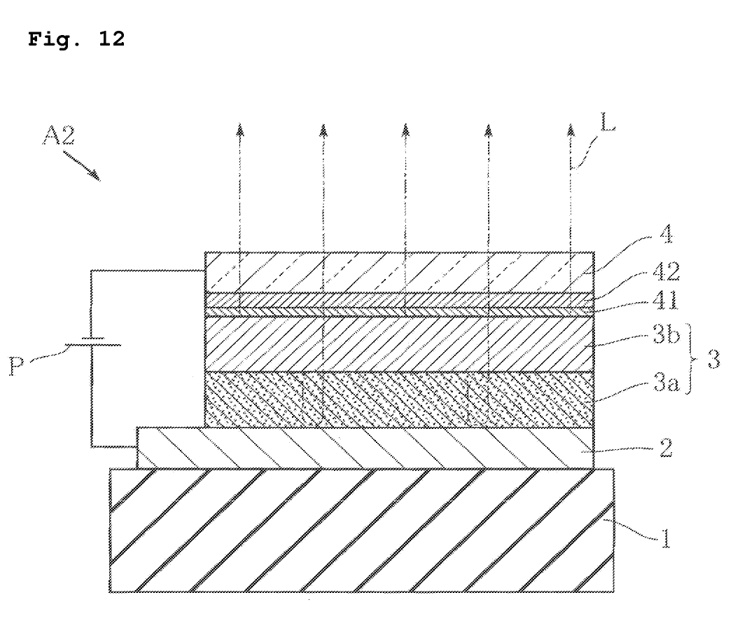

FIG. 12 shows an organic EL element according to a second preferred embodiment of the present invention. Here, from FIG. 12 on, the same symbols are used to indicate elements similar to those in the first preferred embodiment and the descriptions thereof are appropriately omitted.

Organic EL element A2 shown in FIG. 12 is different from the organic EL element A1 in that hole transport layer 3a in organic EL element A2 includes an Mo oxide and is not provided with the same Mo oxide layer 5 as shown in FIG. 1. α-NPD is preferably used as the base material for hole transport layer 3a and an Mo oxide as described above is included in this base material. MoO₃ is preferably used as the Mo oxide.

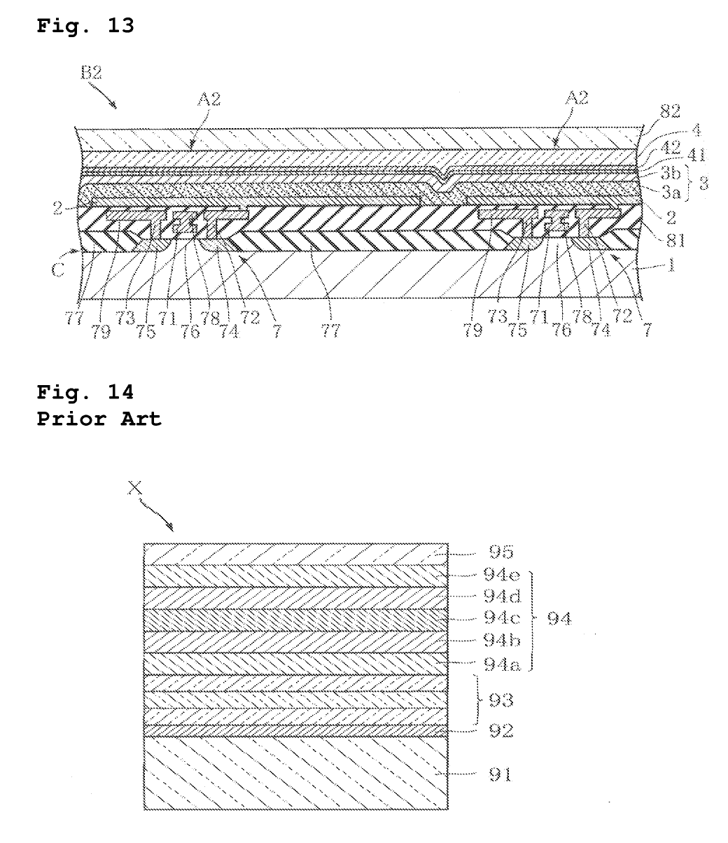

FIG. 13 shows an organic EL display B2 including a plurality of the organic EL element A2. This organic EL display B2 is different from the organic EL display B1 in that organic EL display B2 is provided with a plurality of organic EL elements A2 and its remaining portions are preferably the same as in organic display B1. Hole transport layers 3a of adjacent organic EL elements A2 are connected to each other in organic EL display B2.

Organic EL display B2 including organic EL elements A2 can be manufactured in accordance with a manufacturing method, for example, which is similar to the manufacturing method for an organic EL display B1 that is described in reference to FIGS. 3 to 8. This manufacturing method is different from that for an organic EL display B1, initially in that the formation of the same Mo oxide layer 5, as that shown in FIG. 6, is omitted. In addition, α-NPD which is the base material and MoO₃ which is the Mo oxide are vapor deposited together for the formation of hole transport layer 3a shown in FIG. 7. In accordance with this vapor deposition, hole transport layer 3a, where Mo oxide as described above is distributed relatively uniformly, can be formed.

The effects of increasing the efficiency of hole injection as those described in reference to FIG. 11 were also confirmed by the inventors through experiment in organic EL element A2 of the present preferred embodiment. These effects are considered to be achieved because an Mo oxide made of MoO₃ as described above is included in hole transport layer 3a, and thereby, hole transport layer 3a further functions in the same manner as a so-called hole injection layer. In this manner, organic EL element A2 also makes it possible to achieve an increase in brightness and a reduction in power consumption. In addition, organic EL display B2 can also achieve increase in image quality and reduction in power consumption.

Organic EL elements, organic EL displays and manufacturing methods for an organic EL element according to the present invention are not limited to the various preferred embodiments described above. The specific configuration of each portion of the organic EL elements and organic EL displays according to the present invention can be freely and variously changed in design. In addition, each process included in the manufacturing methods for an organic EL element according to the present invention can be freely and variously changed.

While preferred embodiments of the present invention have been described above, it is to be understood that variations and modifications will be apparent to those skilled in the art without departing the scope and spirit of the present invention. The scope of the present invention, therefore, is to be determined solely by the following claims.

What is claimed is:

1. An organic EL element, comprising:
an anode and a cathode which are arranged so as to face each other;
an organic layer which is disposed between said anode and cathode and includes a light emitting layer; and
an Mo oxide layer disposed between said anode and said organic layer.

2. The organic EL element according to claim 1, wherein said Mo oxide layer is made of MoO₃.

3. The organic EL element according to claim 1, wherein said Mo oxide layer has a thickness of about 3.5 Å to about 1000 Å.

4. The organic EL element according to claim 1, wherein said Mo oxide layer has a thickness of about 10 Å to about 100 Å.

5. The organic EL element according to claim 1, wherein said anode is made of Al.

6. An organic EL display, comprising:
a substrate;
a plurality of organic EL elements according to claim 1 which are supported by said substrate; and
an active matrix circuit arranged to drive said plurality of organic EL elements for light emission.

7. The organic EL display according to claim 6, wherein Mo oxide layers of adjacent organic EL elements of said plurality of organic EL elements are connected to each other.

8. The organic EL display according to claim 6, wherein said substrate is a silicon substrate, and said active matrix circuit includes a plurality transistors on said substrate.

9. A manufacturing method for an organic EL element, comprising the steps of:
forming an anode;
forming an Mo oxide layer after said step of forming an anode;
forming an organic layer which includes a light emitting layer after said step of forming an Mo oxide layer; and
forming a cathode.

10. The manufacturing method for an organic EL element according to claim 9, wherein an Mo oxide layer is formed from MoO₃ in said step of forming an Mo oxide layer.

11. The manufacturing method for an organic EL element according to claim 9, wherein a vapor deposition method is used in said step of forming an Mo oxide layer.

12. The manufacturing method for an organic EL element according to claim 11, wherein the rate of vapor deposition is about 0.1 Å/sec to about 1.0 Å/sec in said vapor deposition method.

13. An organic EL element, comprising:
an anode and a cathode which are arranged so as to face each other; and
an organic layer which is disposed between said anode and cathode and includes a light emitting layer and a hole transport layer; wherein
said hole transport layer includes a base material and an Mo oxide.

14. The organic EL element according to claim 13, wherein said Mo oxide is MoO₃.

15. The organic EL element according to claim 13, wherein said base material is made of α-NPD, TPD or TPTE.

16. The organic EL element according to claim 13, wherein said anode is made of Al.

17. An organic EL display, comprising:
a substrate;
a plurality of organic EL elements according to claim 13 which are supported by said substrate; and
an active matrix circuit arranged to drive said plurality of organic EL elements for light emission.

18. The organic EL display according to claim 17, wherein said substrate is a silicon substrate, and said active matrix circuit includes a plurality of transistors on said substrate.

19. A manufacturing method for an organic EL element, comprising the steps of:
forming an anode;
forming an organic layer which includes a light emitting layer and a hole transport layer; and
forming a cathode; wherein
said step of forming an organic layer includes the step of forming a hole transport layer by vapor depositing a base material and an Mo oxide together.

20. The manufacturing method for an organic EL element according to claim 19, wherein MoO₃ is used as said Mo oxide in said step of forming a hole transport layer.
